(19) United States
(12) Patent Application Publication
(10) Pub. No.: US 2024/0276637 A1
(43) Pub. Date: Aug. 15, 2024

(54) PCB STACK WITH EMBEDDED COMPONENT PACKAGE AND SINTERED VIAS

(71) Applicant: Microchip Technology Caldicot Limited, Caldicot Monmouthshire (GB)

(72) Inventors: George Taylor, Abersychan (GB); Nina Biddle, Coleford (GB); Piers Tremlett, Coleford (GB)

(73) Assignee: Microchip Technology Caldicot Limited, Caldicot Monmouthshire (GB)

(21) Appl. No.: 18/348,404

(22) Filed: Jul. 7, 2023

Related U.S. Application Data
(60) Provisional application No. 63/444,444, filed on Feb. 9, 2023.

(51) Int. Cl. H05K 1/03; H05K 1/11; H05K 1/14; H05K 3/28

(52) U.S. Cl. CPC H05K 1/0366; H05K 1/115; H05K 1/14; H05K 3/284; H05K 2203/1131; H05K 2203/176

(57) ABSTRACT

A method by attaching a component to a first PCB, positioning a prepreg, having a via hole and a component cavity, proximate the first PCB with the component in the component cavity, putting a conductive material in the via hole of the prepreg, positioning a second PCB proximate the first PCB with the component and prepreg between the first PCB and the second PCB, and curing the conductive material to form a sintered via connecting the first PCB with the second PCB. A device with a first PCB, a component attached to the first PCB, a second PCB proximate the first PCB with the component between the first PCB and the second PCB, and a sintered metal via of conductive material connecting the first PCB with the second PCB.

### RELATED PATENT APPLICATION

This application claims priority to commonly owned U.S. Application No. 63/444,444, filed 9 Feb. 2023, the entire contents of which are hereby incorporated by reference for all purposes.

### TECHNICAL FIELD

The present disclosure relates to printed circuit boards (PCBs) with embedded component packages, in particular, PCBs with embedded component packages and printed conductive material vias electrically connecting the PCBs and methods for manufacturing such PCB stacks.

### BACKGROUND

The conventional process to embed components in printed circuit board (PCB) stacks includes interrupting the PCB fabrication process, so that additional copper foils and/or cores may be laminated together with prepregs and later drilled, etched, and plated to allow a component package to be embedded in the PCB stack.

Specifically, a conventional embedded component PCB process adds component packages to the internal layers of the PCBs by soldering, conductive epoxy, sintering or direct via to terminal. To create an electrical connection between the layers bonded during lamination, holes are drilled and plated with copper. These vias may be through hole, blind, microvia (μvia), or other vias. Vias used to connect across the embedded prepreg layers are made by drilling holes and plating the holes with copper. After lamination, the outer copper foil/cores and vias of the PCB stack may continue to be processed.

According to a conventional process, a component package may also be attached to a core PCB, the core PCB having copper layers. In a PCB stack, a core may be a layer of woven glass-reinforced epoxy laminate with a layer of copper on either side. The layer of woven glass-reinforced epoxy laminate may be formed between two smooth foils of copper, to a specified thickness. A prepreg may be a layer of uncured woven glass-reinforced epoxy laminate, that glues together etched cores, or a copper foil to an etched core. The thickness of the prepreg may vary with the height of the etched boards on either side of it. Holes may be drilled through cores to connect buried vias, but the holes may restrict which layers may connect to other layers. A routed, stamped or cut prepreg is placed over the component package, the routed, stamped or cut prepreg having additional copper layers, to form a prepreg stack. The stack is laminated to encapsulate the component package. A laminate may be a laminated prepreg. The stack is then processed by drilling and plating with copper through hole, blind, microvia, or other vias to connect the copper layers in the core PCB with another PCB in the PCB stack. This conventional process produces a PCB stack with embedded component packages attached to a core PCB by component interconnects. A prepreg above the PCB may allow the component package to be embedded above the core PCB. A prepreg positioned below the core PCB may allow a component package to be embedded below the core PCB and may provide additional copper layers. Through/blind vias are drilled and plated with copper to connect the copper layers of the PCBs above and below the embedded component package attached to a core PCB.

Conventional processes rely on electroplated through-via, blind via, or micro-via processes to connect copper layers of PCBs together after embedding component packages in a prepreg to a PCB. Embedded component packages are conventionally processed on existing, large PCB panel formats of 12″×18″, which adds significant cost and risk of failure, as more circuits (and component packages) are added to the PCB panel to make the process cost effective. However, the downside to large PCB panel formats is increased risk of catastrophic yield loss should an entire PCB panel be scrapped.

The costs and lead times of manufacturing PCB stacks with component packages embedded inside are higher and longer than the costs and lead times of manufacturing PCB stacks without embedded component packages.

There is a need for a cheaper and less time consuming manufacturing process to manufacture PCB packages with embedded components and PCBs electrically connected by vias.

### SUMMARY

According to an aspect, there is provided a method comprising: attaching a component to a first printed circuit board; positioning a prepreg, having a via hole and a component cavity, proximate the first printed circuit board with the component in the component cavity; putting a conductive material in the via hole of the prepreg; positioning a second printed circuit board proximate the first printed circuit board with the component and prepreg between the first printed circuit board and the second printed circuit board; and curing the conductive material to form a sintered via connecting the first printed circuit board with the second printed circuit board, whereby a PCB stack is formed.

An aspect provides a device comprising: a printed circuit board stack comprising: a first printed circuit board; a component attached to the first printed circuit board; a second printed circuit board proximate the first printed circuit board with the component between the first printed circuit board and the second printed circuit board; and a sintered via comprising conductive material connecting the first printed circuit board with the second printed circuit board.

An aspect provides a method comprising: stacking a plurality of laminate sheets into a laminate sheet stack to make a prepreg body; forming a component cavity in the prepreg body; masking the component cavity with a mask; and making a via hole through the mask and the body.

### BRIEF DESCRIPTION OF THE DRAWINGS

The figures illustrate example PCB packages with embedded components and printed conductive material vias connecting the PCBs, and further illustrate methods of manufacturing embedded component packages having printed conductive material vias connecting finished top and bottom printed circuit boards, and manufacturing prepregs with printed conductive material vias.

FIGS. 1A-1E illustrate cross-sectional, side views of a PCB stack with an embedded component package at various moments in a process for manufacturing PCB stacks having printed vias connecting finished top and bottom printed circuit boards.

FIG. 2 illustrates a cross-sectional, side view of a PCB stack with an embedded component package, wherein sintered vias connect finished top and bottom printed circuit boards.

FIGS. 3A-3F illustrate cross-sectional, side views of a PCB stack with an embedded component package at various moments in a manufacturing process for manufacturing the PCB stack with an embedded component package.

FIGS. 4A-4D illustrate cross-sectional, side views of a prepreg at various moments in a manufacturing process of the prepreg.

FIG. 5 shows a top view of a printed circuit board having attached components, wherein a prepreg is placed on the printed circuit board so the components are received in component cavities in the prepreg.

FIGS. 6A-6D show cross-sectional, side views of a PCB with a component package and a prepreg at various moments of conductive material being printed into via holes of the prepreg.

FIG. 7 shows a flow chart of a method for manufacturing embedded component packages having printed vias connecting finished top and bottom printed circuit boards.

FIG. 8 shows a flow chart of a method for manufacturing a prepreg with a hole for a via.

FIG. 9 shows a flow chart of a method for manufacturing a prepreg with a printed conductive material via.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

Aspects provide embedded component packages having sintered vias connecting finished top and bottom printed circuit boards and methods for manufacturing prepregs and embedded component packages.

A component may be attached to a first printed circuit board. A plurality of epoxy resin laminate sheets may be stacked into a laminate sheet stack to make a prepreg body. The epoxy resin laminate sheets may be routed, stamped or cut to form a component cavity in the prepreg body. The component cavity may be masked by placing a film over the component cavity. A hole may be made through the film and the body by drilling through the prepreg. The prepreg may be positioned proximate the first printed circuit board with the component positioned in the component cavity of the prepreg. A via may be printed by working flowable conductive material into the hole of the prepreg, while the mask precludes conductive material from entering the component cavity. A flowable conductive material may be put in the hole by printing, flowing, or injecting without limitation into the hole. Alternatively, a solid or semi-solid conductive material may be pushed, pressed, or injected without limitation into the hole, which may negate the use of the mask. The prepreg may be unmasked by removing the film from the component cavity. Encapsulant material may be added to the component cavity. A second printed circuit board may be positioned proximate the first printed circuit board with the component and prepreg between the first printed circuit board and the second printed circuit board, to form a PCB stack. The flowable conductive material may be sintered to form a sintered via to connect the first printed circuit board with the second printed circuit board.

A prepreg is a pre-impregnated insulation layer, such as a dielectric material, which prepreg is sandwiched between two cores or between a core and a copper foil in a PCB to provide insulation and may bind the two cores or the core and a copper foil. A prepreg may be a glass fiber weave/cloth impregnated with a resin bonding agent. More broadly, a prepreg may be a stack of epoxy resin laminate sheets.

The prepreg may comprise a thermoset epoxy resin that starts as a liquid and fully impregnates a fiber reinforcement. The epoxy resin may undergo partial curing, which changes the state of the resin from liquid to a solid, which is the “B-stage.” In the B-stage, the resin is partially laminated, and may be tacky. When the resin is brought up to an elevated temperature, it returns to a liquid state prior to hardening completely. Once laminated, the thermoset resin is fully cross-linked.

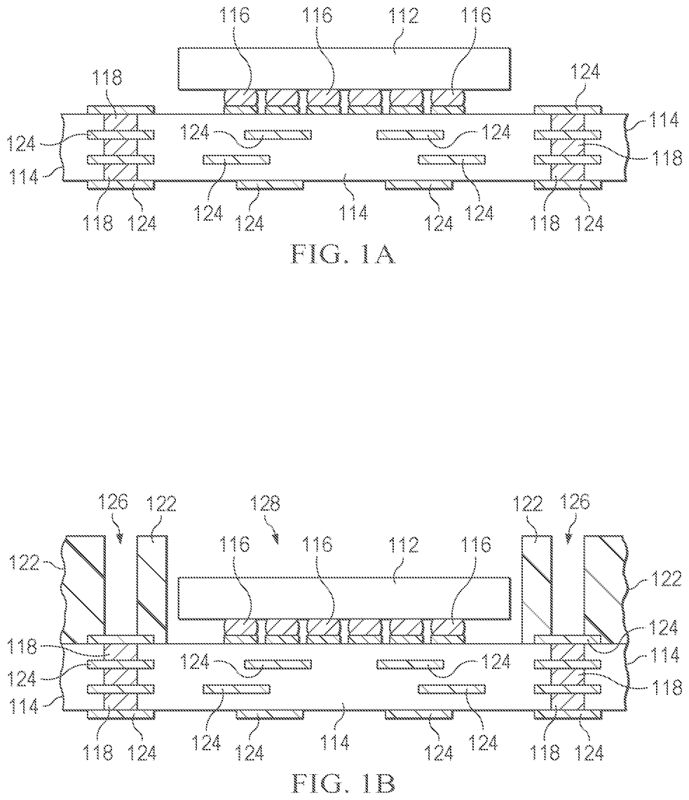

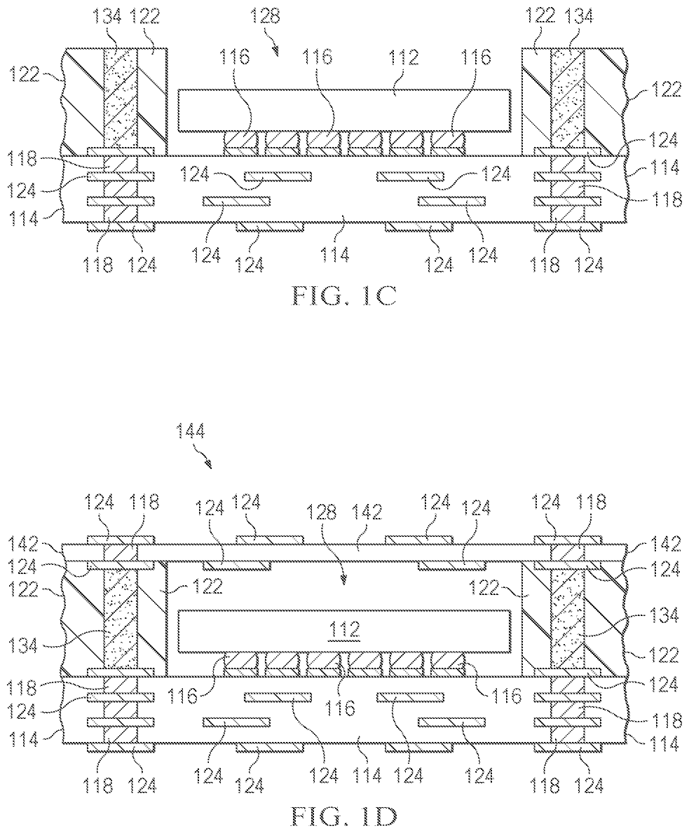

A component may be attached to a first PCB (see FIG. 1A) and encapsulated with prepregs between two additional PCBs. See FIG. 1E. Vias between the two additional PCBs may be added in which conductive material is printed, flowed or injected into pre-drilled holes in the prepreg. The conductive material printed, flowed or injected into pre-drilled holes in the prepreg may be sintered to form sintered vias to connect copper features on both of the PCBs, completing an electrical connection between them. Once the embedded component process is complete, the finished PCB stack is ready for other PCBA processes such as surface-mount technology (SMT) on the outer layers of the finished PCB stack.

According to some aspects, there may be no need for electroplating equipment or line to connect copper layers after embedding components between two PCBs. PCB fabrication processes may not need to be interrupted to embed components. The cost of a PCB with embedded components may be reduced and manufacturing processes may produce lower yield loss, lower premium costs, and allow less sophisticated facilities to manufacture the PCB stacks. Aspects produce finished PCB stacks with embedded components at lower cost and shortened manufacturing lead-time. Aspects may provide for relatively smaller PCB stack sizes depending on tolerances.

Aspects use sintered vias to make electrical connections between the copper layers above and below the embedded components. Prepregs may be routed, stamped or cut with cutouts for the component packages to sit within and the prepregs may be laid over the component packages. Enough prepreg layers are added or stacked to achieve the prepreg height needed to embed the components. A copper foil or core may be added above the prepreg. This stack of material may then be laminated in a press which causes the prepreg epoxy to flow and cure, whereby the component package becomes encapsulated and the PCBs are attached together as a PCB stack. This lamination step embeds the component packages(s) within the PCB stack.

Sintered vias may electrically connect the copper layers above and below the components. After the prepregs are routed, stamped or cut for the component cavities, a plastic film may be added to the top of the prepreg and the stack may be tacked to a first PCB, via holes may then be laser drilled down to the first PCB. The stack may be tacked to the first PCB by partially curing, which changes the state of the resin from liquid to a solid (“B-stage”). In the B-stage, the resin is partially laminated, and may be tacky. Once the via holes are drilled, a conductive material (transient liquid phase sinter material, conductive adhesive, silver sinter, copper sinter, hybrid epoxy/sinter paste, or sinter paste, without limitation) may be printed, flowed or injected into the openings until they are filled with the conductive material. The plastic film may be removed to expose the prepreg. A second PCB may then be added to the top of the prepreg stack and the entire PCB stack may be laminated. Lamination embeds the component packages and also cures/sinters the conductive material in position, which thus form sintered vias between the first and second PCBs. Lamination is the process of making the resin in the prepreg flow and cure in the structure under high temperature and pressure. Sintering is the process of curing a sinter material under high temperature and pressure. Temperature and pressure conditions sufficient for lamination may be the same as temperature and pressure conditions sufficient for sintering. After lamination, the PCB stack is ready for further PCBA processing and does not need to continue any PCB fabrication processes such as drilling, etching, or plating to form vias.

The conductive material may be a transient liquid phase sinter, conductive adhesive, or sinter paste, without limitation. A sinter paste may be a combination of small particles of solder materials with small particles of solderable metals in a fluxing polymer binder. During lamination of the PCB stack, the conductive material may be cured. Curing a sinter paste may include heating until the solder particles melt, the melted solder wets the solderable particles, and an interconnected metallic mesh is formed as the melted solder cools and solidifies around the solderable particles.

In another aspect, via holes may be mechanically drilled in the prepreg before tacking the prepreg to the first PCB.

FIGS. 1A-1E illustrate cross-sectional, side views of a PCB stack at various moments in a process for manufacturing embedded components in PCB stacks. A component 112 is attached to a finished first PCB 114 by component interconnects 116, the PCB 114 having copper layers 124 and vias 118. See FIG. 1A. In one example vias 118 may comprise μvias. The PCB 114 may have μvias 118 or any form of via to complete any electrical connection to additional layers, which may be design dependent. A sintered via may provide electrical connections between two copper layers adjacent to an embedded section. A routed, stamped or cut and drilled prepreg 122 is placed on the PCB 114. Via holes 126 are pre-drilled in the prepreg 122 and a component cavity 128 is pre-routed, stamped or cut. See FIG. 1B. The prepreg 122 is placed on the PCB 114 such that the component 112 is in the component cavity 128. Conductive material 134, such as sinter material, is printed, flowed or injected into the via holes 126 of the prepreg 122. In particular, the conductive material 134 may be a transit liquid phase sinter (TLP S), conductive adhesive, silver sinter, copper sinter, hybrid epoxy/sinter paste, or sinter paste, without limitation, and may be printed, flowed or injected into the drilled via holes 126. See FIG. 1C. A finished second PCB 142 is placed above the prepreg 122 with the component 112 and via holes between the first PCB 114 and the second PCB 142 to form a PCB stack 144. See FIG. 1D. The PCB stack 144 is pressed and heated to laminate the stack, whereby the component 112 is encapsulated with molten fluid material, which may be a material similar to the prepreg 122, and to cure the conductive material 134 to form sintered vias 132 connecting the first PCB 114 to the second PCB 142. See FIG. 1E. One way to cure the conductive material 134 is by sintering.

Microvias are small micro-holes through which the layers of a multi-layer PCB remain connected. Microvias are sometimes referred to as uVias. Microvias have a conical frustum shape, sloping inwards as they make a layer transition and terminate at a pad in the next layer. A microvia may span a single layer, or multiple microvias may be stacked to form a connection across multiple layers in a PCB.

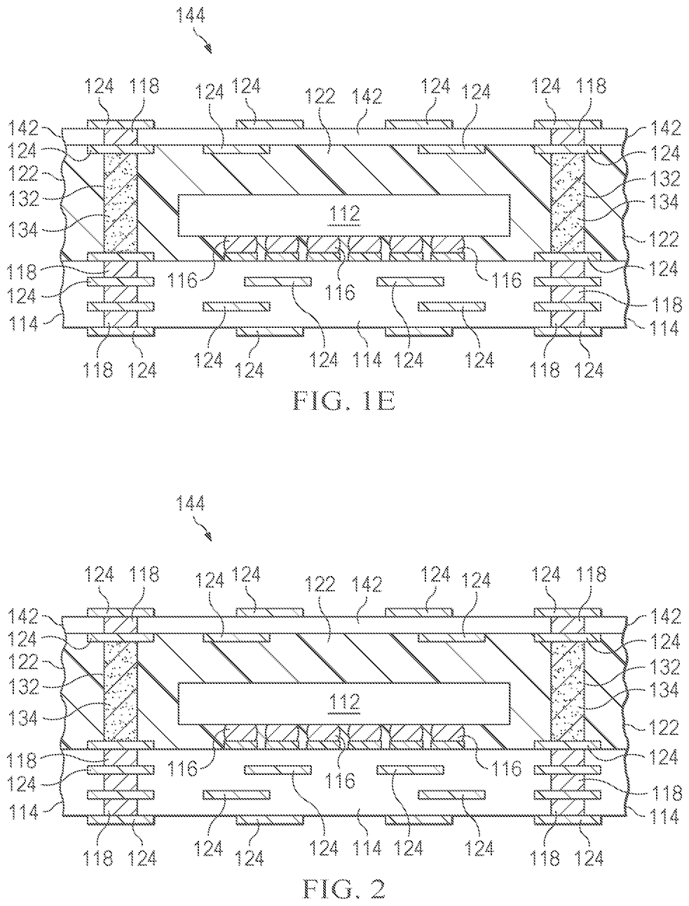

FIG. 2 shows a cross-sectional side view of a PCB stack 144 having an embedded component package 112 having sintered vias 132. The PCB stack 144 has a component package 112 embedded between a first PCB 114 and a second PCB 142. The component package 112 is attached to the first PCB 114 by component interconnects 116. A prepreg 122, between the first PCB 114 and the second PCB 142, embeds the component package 112. Sintered vias 132 connect microvias 118 of the first PCB 114 with microvias 118 of the second PCB 142.

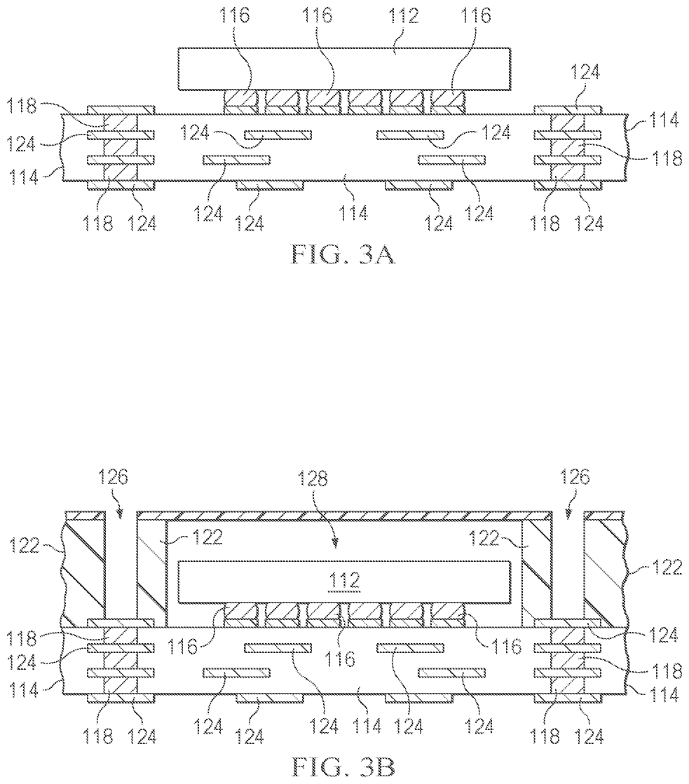

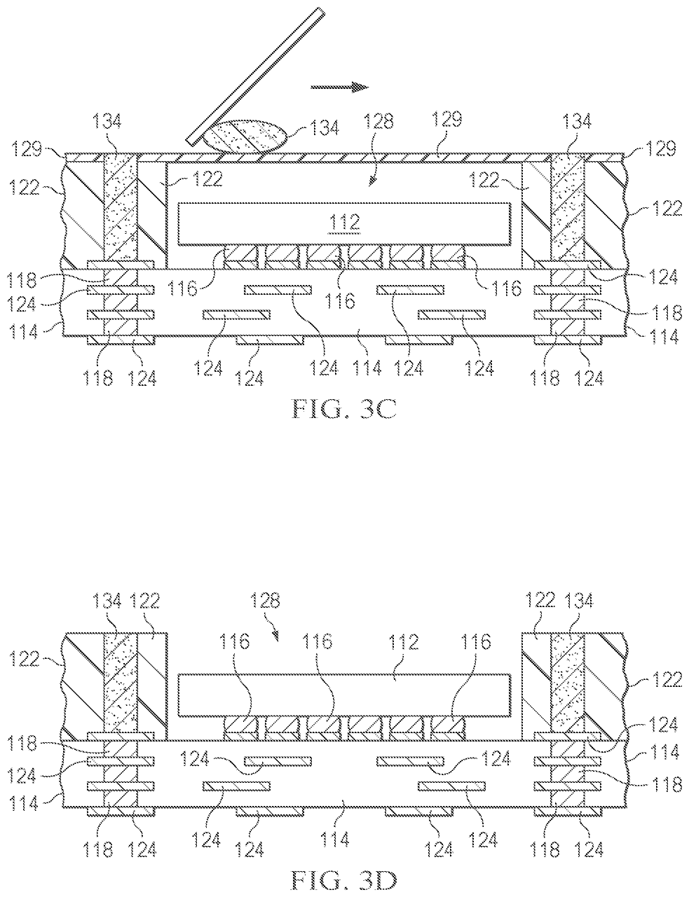

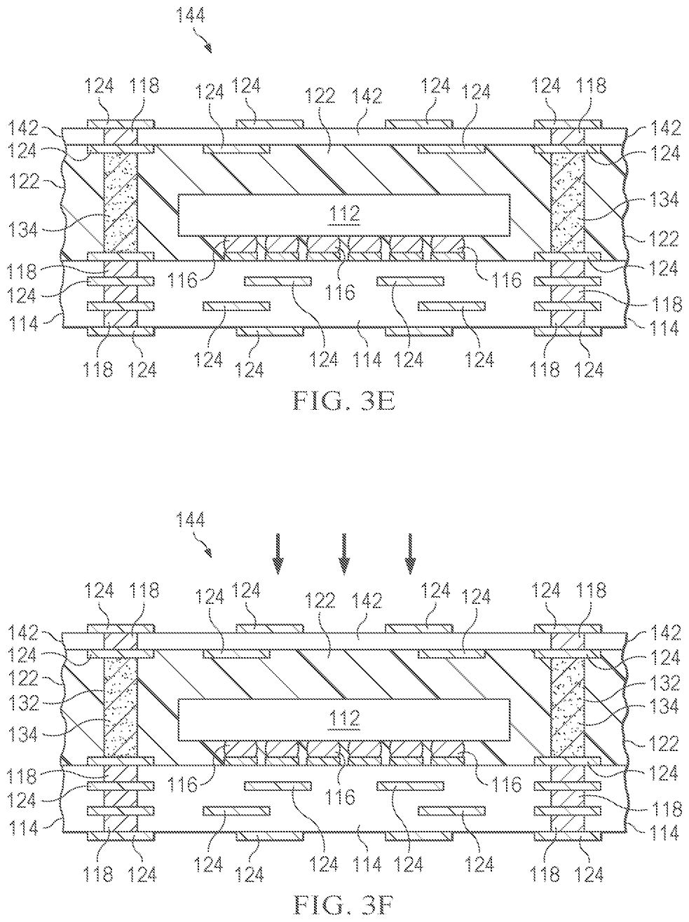

FIGS. 3A-3F illustrate cross-sectional, side views of a PCB stack at various moments of a process for manufacturing a PCB stack with an embedded component package. As shown in FIG. 3A, a component package 112 is attached to a finished first PCB 114 by component interconnects 116. The finished first PCB 114 has copper layers 124 and μvias 118. A routed, stamped or cut and drilled prepreg 122 is placed over the component 112 on the PCB 114. See FIG. 3B. Referring to FIG. 3C, conductive material 134 is printed, flowed or injected into the via holes 126 of the prepreg 122. In particular, conductive material 134 (for example, a transit liquid phase sinter (TLPS), conductive adhesive, silver sinter, copper sinter, hybrid epoxy/sinter paste, or sinter paste, without limitation) may be applied to the film 129 and wiped across the film 129 to work the conductive material 134 into the via holes 126 until the via holes 126 are completely filled with conductive material 134. As shown in FIG. 3D, the film 129 is then removed from the top of the prepreg 122 leaving the conductive material 143 in the via holes 126. Referring to FIG. 3E, a finished second PCB 142 is placed above the prepreg 122 with the component package 112 and conductive material 134 between the first PCB 114 and the second PCB 142 to form a PCB stack 144. Liquid state encapsulation material may be flowed into the component cavity 128 until the component package 112 is completely covered, wherein the encapsulation material may be similar to the epoxy of the prepreg 122. The PCB stack 144 is pressed and heated to laminate the stack, whereby the component 112 is encapsulated with solidified encapsulation material similar to material of the prepreg 122 and the conductive material 134 in via holes 126 is sintered or cured to form sintered vias 132 connecting the first PCB 114 with the second PCB 142. See FIG. 3F.

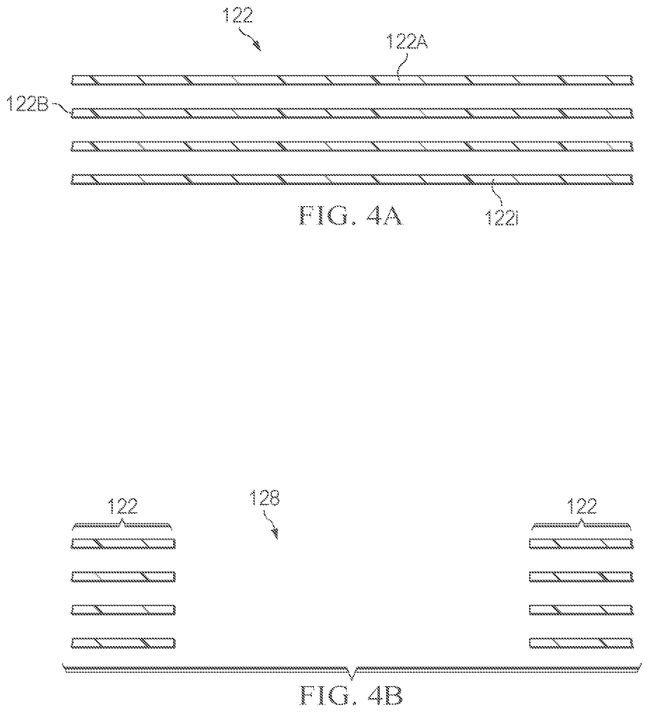

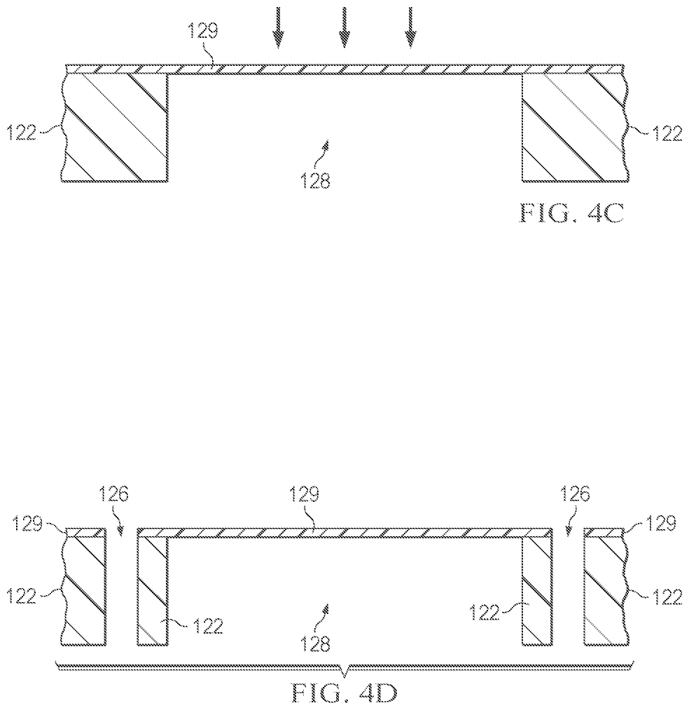

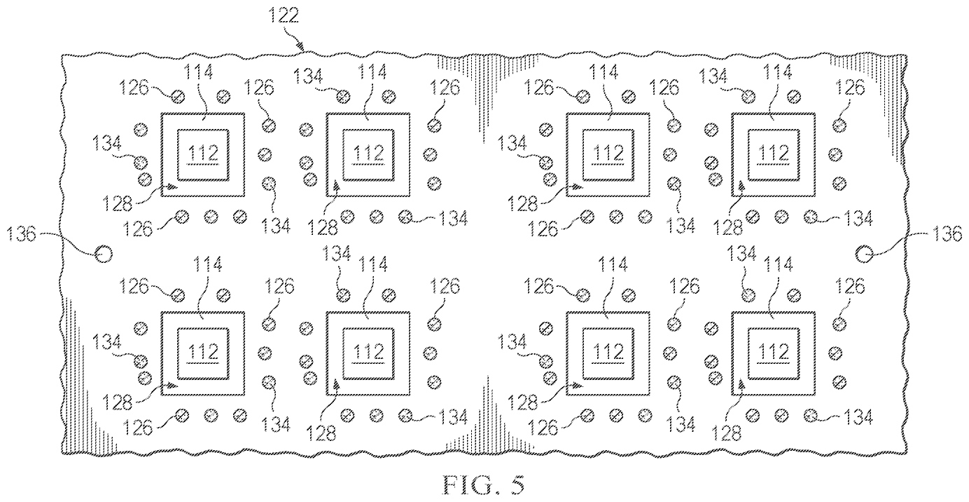

FIGS. 4A-4D illustrate a process for preparing the prepreg 122 shown in FIGS. 3B-3C. As shown in FIG. 4A, multiple laminate sheets or layers 122A, 122B, . . . 122i of woven glass-reinforced epoxy laminate may be stacked on top of one another to achieve a prepreg 122 having a total height tall enough to embed the component package 112 (see FIG. 3B). Referring to FIG. 4B, a component cavity 128 large enough to receive the component package 112 is formed in the prepreg 122. The component cavity 128 may be routed with a router or stamped/cut with a press. As shown in FIG. 4C, the laminate sheets 122A, 122B, . . . 122i are tacked together at a lower temp/pressure than used for lamination to avoid curing of the epoxy of the laminate sheets, wherein the temperature/pressure is high enough to achieve a tacky property of the epoxy to bond the laminate sheets together, but not high enough so as to bond the laminate sheets together. A film 129 is tacked to the top of the prepreg 122 to act as stencil/mask during a forthcoming via printing process. A film 129 may be tacked by a hot roller press with reduced heat and pressure than is sufficient for full cure. As shown in FIG. 4D, via holes 126 are drilled (mechanical or laser) through the film 129 and the tacked laminate sheets 122A, 122B, . . . 122i, after which the prepreg 122 is ready to be placed over the component 112 on the PCB 114. See FIG. 3B.

FIG. 5 shows a top view of a prepreg 122 having eight component cavities 128 positioned on a PCB 114 with eight component packages 112, wherein film 129 has been removed. See FIG. 3D. Several via holes 126 filled with conductive material 134 are shown around each component cavity 128. The via holes 126 filled with conductive material 134 have a circular area cross-section parallel to the first printed circuit board 114. Tooling holes 136 are provided to position the PCB 114 in tooling machines for production.

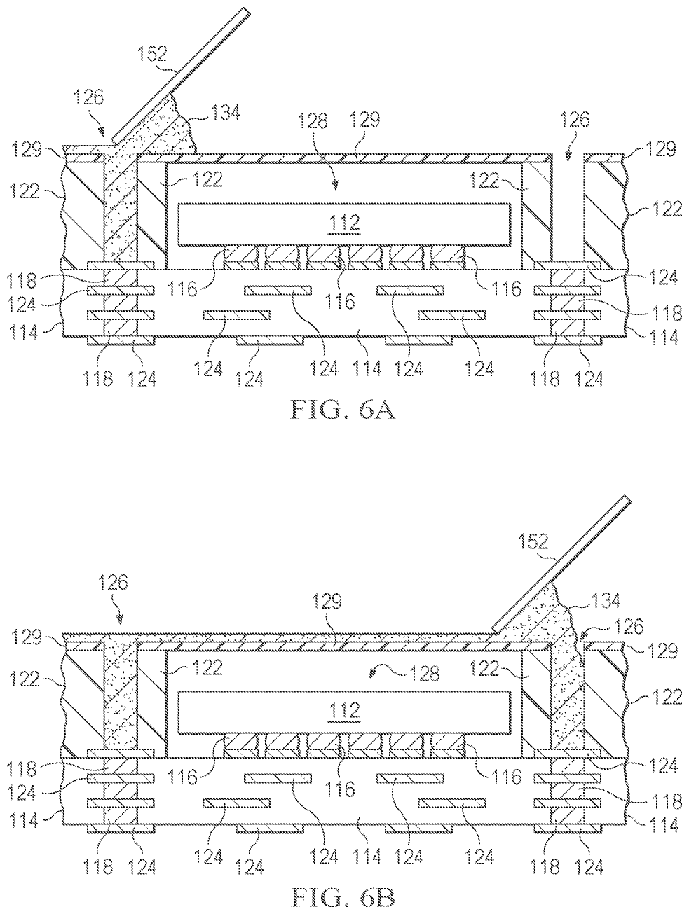

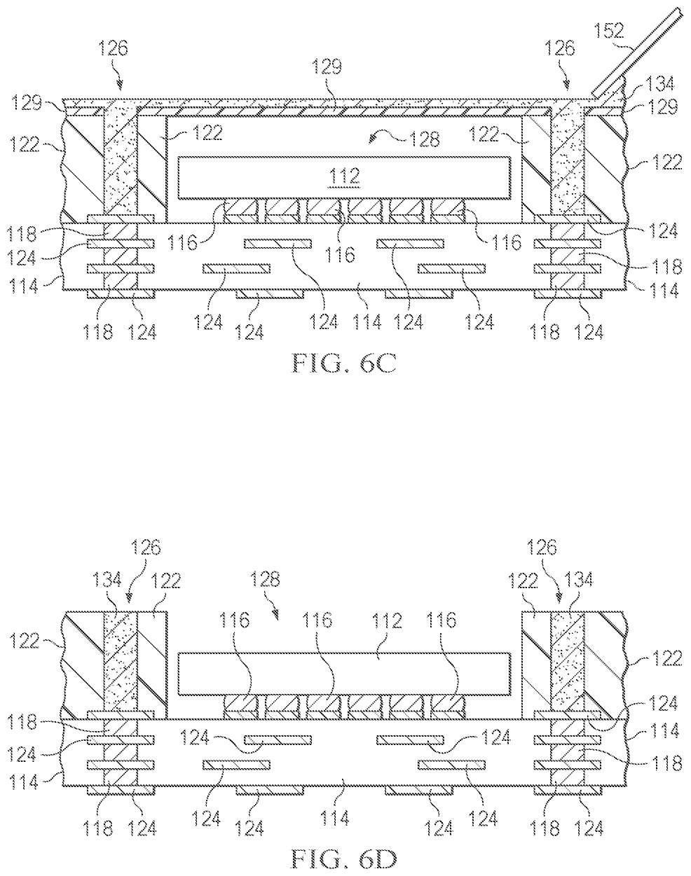

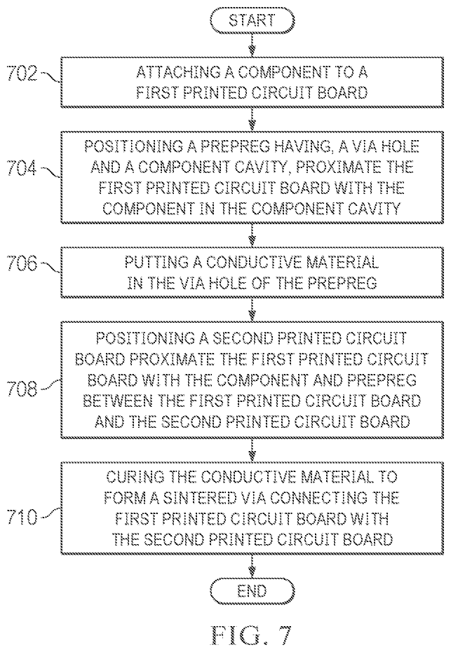

FIGS. 6A-6D show cross-sectional, side views of a first PCB 114 with a component package 112 and a prepreg 122 at various moments in a process of printing conductive material 134 to form sintered vias. As shown in FIG. 6A, a prepreg 122 having a component cavity 128 is positioned on a first PCB 114 so that a component package 112 is in the component cavity 128. The prepreg 122 has a film 129 masking the component cavity 128. A wiper blade 152 is printing conductive material 134 into via holes 126 in the prepreg 122 by wiping the conductive material 134 across the film 129. As shown in FIG. 6A, a first via hole 126 is completely filled with conductive material 134. As shown in FIG. 6B, a first via hole 126 is completely filled with conductive material 134 and a second via hole 126 is partially filled with conductive material 134 as the wiper blade 152 wipes across the film 129. As shown in FIG. 6C, both via holes 126 are completely filled with conductive material 134. FIG. 6D shows the first PCB 114 with the component package 112, and the prepreg 122 after the film 129 (see FIG. 6C) has been removed leaving the conductive material 134 in the via holes 126.

In alternatives, the conductive material may be placed in a via hole in a prepreg by printing, flowing, injecting, pushing, or hammering, without limitation. A flowable conductive material may be put in the hole in a prepreg by printing, flowing, or injecting without limitation. Where the conductive material is flowable, a mask may facilitate placing the conductive material in a via hole. A solid or semi-solid conductive material may be pushed, pressed, injected, inserted, or hammered, without limitation, into the hole. Where the conductive material is solid or semi-solid, the conductive material may be placed in a via hole without a mask on the prepreg.

FIG. 7 shows a flow chart of a method for manufacturing embedded component packages having sintered vias connecting finished top and bottom printed circuit boards. A component is attached 702 to a first printed circuit board. A prepreg is positioned 704 having a via hole and a component cavity, proximate the first printed circuit board with the component positioned in the component cavity. The method is being described in relation to a single component mounted on the bottom printed circuit board with a single component cavity, however this is not meant to be limiting in any way, and multiple components with associated respective cavities may be utilized without exceeding the scope. Conductive material is put 706 in the vial hole of the prepreg. A second printed circuit board is positioned 708 proximate the first printed circuit board with the component and prepreg between the first printed circuit board and the second printed circuit board. The conductive material is cured 710 to form a sintered via connecting the first printed circuit board with the second printed circuit board.

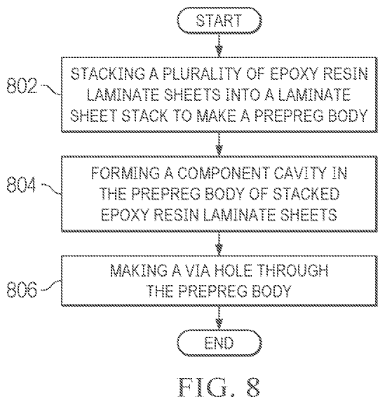

FIG. 8 shows a flow chart of a method for manufacturing a prepreg with a hole for a via. A plurality of epoxy resin laminate sheets are stacked 802 into a laminate sheet stack to make a prepreg body. A component cavity is formed in the prepreg body of stacked epoxy resin laminate sheets 804. The component cavity may be formed by routing or by stamping or cutting. Alternatively, each of the laminate sheets may have a component cavity prior to stacking. A via hole is made 806 through the prepreg body.

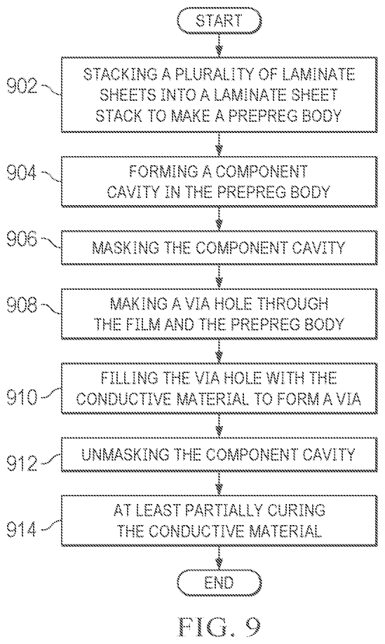

FIG. 9 shows a flow chart of a method for manufacturing a prepreg with a printed conductive material via. A plurality of epoxy resin laminate sheets are stacked 902 into a laminate sheet stack to make a prepreg body. A component cavity is formed in the prepreg body. The component cavity may be formed by routing, stamping or cutting 904. Alternatively, each of the laminate sheets may have a component cavity formed prior to stacking 902. The component cavity is masked 906. Masking may be by placing a film over the component cavity. A via hole is made 908 through the film and the prepreg body. The via hole is filled 910 with the conductive material to form a filled via. The component cavity is unmasked 912. Unmasking may be by removing a film from the component cavity. The conductive material of the filled via is a least partially cured 914 to at least partially solidify the conductive material so as to form a partially sintered via. A partially cured conductive material is solidified sufficiently to allow the prepreg to be produced as a stand alone product, wherein the prepreg may be handled without the conductive material falling out of the via. When the stand alone prepreg is added to a PCB stack, the conductive material may be fully cured to electrically connect two PCBs.

Although examples have been described above, other variations and examples may be made from this disclosure without departing from the spirit and scope of these disclosed examples.

1. A method comprising:
attaching a component to a first printed circuit board;
positioning a prepreg, having a via hole and a component cavity in a prepreg body, proximate the first printed circuit board with the component in the component cavity;
putting a conductive material in the via hole of the prepreg;
positioning a second printed circuit board proximate the first printed circuit board with the component and prepreg between the first printed circuit board and the second printed circuit board; and
curing the conductive material to form a sintered via connecting the first printed circuit board with the second printed circuit board, whereby a PCB stack is formed.

2. The method as in claim 1, comprising preparing the prepreg by stacking a plurality of laminate sheets into a laminate sheet stack to make the prepreg body.

3. The method as in claim 2, comprising flowing encapsulation material over the component in the cavity of the body and heating a material of the plurality of laminate sheets and the encapsulation material to laminate the prepreg and encapsulate the component.

4. The method as in claim 1, comprising flowing encapsulation material over the component in the cavity of the body.

5. The method as in claim 1, comprising preparing the prepreg forming the component cavity by routing.

6. The method as in claim 1, comprising preparing the prepreg by masking the component cavity with a film, making the via hole through the film and the body, and wherein putting a conductive material in the via hole of the prepreg comprises filling the via hole with the conductive material.

7. The method as in claim 6, wherein the conductive material is selected from a group consisting of: transient liquid phase sinter material, sinter paste, silver sinter, copper sinter, and hybrid epoxy/sinter paste.

8. The method as in claim 6, wherein preparing the prepreg comprises removing the film from the body.

9. The method as in claim 1, wherein curing the conductive material comprises heating the conductive material.

10. A device comprising:
a first printed circuit board;
a component attached to the first printed circuit board;
a second printed circuit board proximate the first printed circuit board with the component between the first printed circuit board and the second printed circuit board; and
a sintered via comprising conductive material connecting the first printed circuit board with the second printed circuit board.

11. The device as in claim 10, wherein the sintered via comprises a circular area cross-section parallel to the first printed circuit board.

12. The device as in claim 10, comprising a prepreg between the first printed circuit board and the second printed circuit board.

13. The device as in claim 10, comprising encapsulation material between the first printed circuit board and the second printed circuit board.

14. The device as in claim 10, wherein the conductive material is selected from a group consisting of: transient liquid phase sinter material, sinter paste, silver sinter, copper sinter, and hybrid epoxy/sinter paste.

15. The device as in claim 10, wherein the first printed circuit board has a first microvia and the second printed circuit board has a second microvia, wherein the sintered via connects the first microvia with the second microvia.

16. The device as in claim 13, wherein the encapsulation material is laminated.

17. A method comprising:
stacking a plurality of laminate sheets into a laminate sheet stack to make a prepreg body;
forming a component cavity in the prepreg body; and
making a via hole through the body.

18. The method as in claim 17, wherein forming a component cavity comprises routing the component cavity in the prepreg body.

19. The method as in claim 17, comprising:
masking the component cavity;
filling the hole with a flowable conductive material;
unmasking the component cavity; and
at least partially curing the conductive material.

20. The method as in claim 19, comprising putting a solid or semi-solid conductive material in the via hole.
